(19) United States
(12) Patent Application Publication
(10) Pub. No.: US 2025/0336684 A1
(43) Pub. Date: Oct. 30, 2025

(54) METHOD FOR MANUFACTURING PACKAGED DEVICE CHIPS

(71) Applicant: DISCO CORPORATION, Tokyo (JP)

(72) Inventors: Shigeya KURIMURA, Tokyo (JP); Hayato KIUCHI, Tokyo (JP); Chisato YAMADA, Tokyo (JP)

(73) Assignee: DISCO CORPORATION, Tokyo (JP)

(21) Appl. No.: 19/184,237

(22) Filed: Apr. 21, 2025

(30) Foreign Application Priority Data
Apr. 26, 2024 (JP) 2024-072208
Apr. 3, 2025 (JP) 2025-061834

(51) Int. Cl. H01L 21/48; H01L 21/56

(52) U.S. Cl. CPC H01L 21/4842; H01L 21/4835; H01L 21/561

(57) ABSTRACT

A method for manufacturing packaged device chips by dividing a package substrate, on which device chips arrayed on a lead frame are sealed with a mold resin, along divide-preset lines, is provided. The method includes a package substrate forming step including forming the package substrate by sealing the device chips arrayed on supporting sections of the lead frame and electrodes, each having a recess which is open on a second surface side of the lead frame, with the mold resin; a recess coating step including coating each of the recesses at least partly with a coating material; a dividing step including dividing regions including the recesses coated with the coating material along the divide-preset lines to produce the packaged device chips; and a removing step including jetting a high-pressure fluid at the coating material coating the recesses to remove the coating material from the recesses.

### CROSS REFERENCE TO RELATED APPLICATION

This application is based upon and claims the benefit of priority from the prior Japanese Patent Application No. 2024-072208 filed on Apr. 26, 2024 and the prior Japanese Patent Application No. 2025-061834 filed on Apr. 3, 2025; the entire contents of which are incorporated herein by reference.

### FIELD

The present disclosure relates to a method for manufacturing packaged device chips.

### BACKGROUND

For manufacturing packaged device chips, on an upper surface of a package substrate such as QFN (Quad Flat Non-leaded) substrate, recesses (cavities) may be formed in an arrangement to intersect with divide-preset lines. As the package substrate is cut and divided with, for example, a cutter blade, the recesses may be divided at the intersections with the divide-preset lines and exposed at cross sections (sideward surfaces) of the individually divided chips. Accordingly, fibrous burrs may be created on edges along inner surfaces of the recesses.

In this regard, a method to remove such burrs created in the recesses from the package substrate with high-pressure water is disclosed in, for example, Japanese Patent Laid-Open Publication No. 2016-181569.

### SUMMARY

According to the method disclosed in the above-referenced publication, while the burrs may be removed with the high-pressure water, the method may not prevent the package substrate from forming of burrs. Moreover, the burrs formed in the package substrate by the cutting process are made of a metal, and the space inside each recess is narrow; therefore, removing the burrs with the high-pressure water may be difficult. As such, manufacturing packaged device chips by dividing a package substrate may have been difficult.

In view of this difficulty, the present disclosure is aimed at providing a method for manufacturing packaged device chips from a package substrate having recesses, in which burr formation may be reduced.

According to an aspect of the present disclosure, a method for manufacturing packaged device chips by dividing a package substrate, on which device chips arrayed on a lead frame are sealed with a mold resin, along divide-preset lines, is provided. The lead frame includes a plurality of supporting sections to support the device chips on a first surface side thereof and a plurality of electrodes formed on outsides of the supporting sections. The plurality of electrodes each include a recess which is open on a second surface side of the lead frame opposite to the first surface side. The recess is formed in a region to overlap any of the divide-preset lines. The method includes a package substrate forming step including forming the package substrate by sealing the device chips arrayed on the supporting sections and the plurality of electrodes with the mold resin; a recess coating step including coating each of the recesses at least partly with a coating material; a dividing step including dividing regions including the recesses coated with the coating material along the divide-preset lines to produce the packaged device chips; and a removing step including jetting a high-pressure fluid at the coating material coating the recesses to remove the coating material from the recesses.

Optionally, each of the plurality of electrodes may have an opening continuous with the recess therein on the second surface side. The opening is open on any sideward surface of the electrode without dividing the electrode apart. The recess coating step includes causing the mold resin to flow into the recesses through the openings in the package substrate forming step.

Optionally, the dividing step may include a first dividing step including forming first process grooves having a depth from the second surface side that does not divide the package substrate apart; and a second dividing step including forming second process grooves, which are continuous respectively with the first process grooves and dividing the package substrate apart. The removing step may be performed between the first dividing step and the second dividing step.

According to the method for manufacturing the packaged device chips of the present disclosure, for manufacturing the package substrate having recesses, burrs to be formed in the package substrate may be reduced.

### BRIEF DESCRIPTION OF THE DRAWINGS

FIG. 1 is a schematic perspective view of a package substrate for manufacturing packaged device chips according to a first embodiment.

FIGS. 2 is an enlarged view of a region A in a lead frame shown in FIG. 1.

FIG. 3 is a schematic cross-sectional view to illustrate a device stacking step according to the first embodiment.

FIG. 4 is a schematic view to illustrate a package substrate forming step (recess coating step) according to the first embodiment.

FIG. 5A is a perspective view of a recesses formed in electrodes in a comparative example.

FIG. 5B is a perspective view of an example of recesses formed in electrodes.

FIG. 5C is a perspective view of another example of recesses formed in electrodes.

FIG. 6 is a schematic view to illustrate a dividing step according to the first embodiment.

FIG. 7 is a schematic view to illustrate a removing step according to the first embodiment.

FIG. 8 is a schematic view to illustrate a first dividing step according to a second embodiment.

FIG. 9 is a schematic view to illustrate a removing step according to the second embodiment.

FIG. 10 is a schematic view to illustrate a second dividing step according to the second embodiment.

FIG. 11 is a schematic view to illustrate a package substrate forming step according to a third embodiment.

FIG. 12A is a schematic view to illustrate a recess coating step according to the third embodiment.

FIG. 12B is another schematic view to illustrate the recess coating step according to the third embodiment.

FIG. 13A is a schematic view to illustrate a variation of the recess coating step according to the third embodiment.

FIG. 13B is a schematic view to illustrate another variation of the recess coating step according to the third embodiment.

FIG. 13C is a schematic view to illustrate another variation of the recess coating step according to the third embodiment.

### DESCRIPTION OF EMBODIMENTS

### First Embodiment

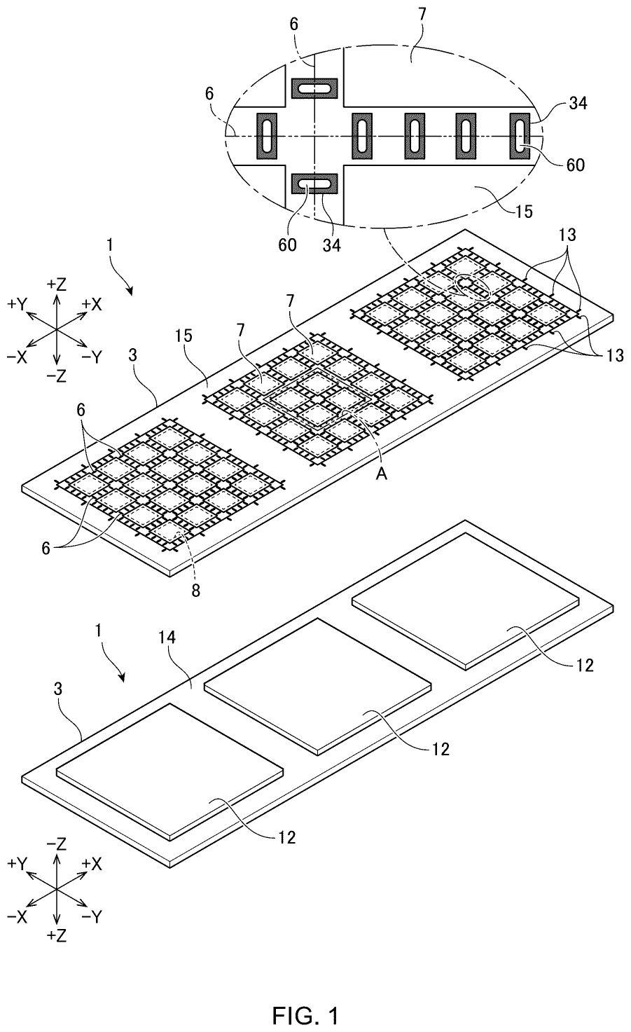

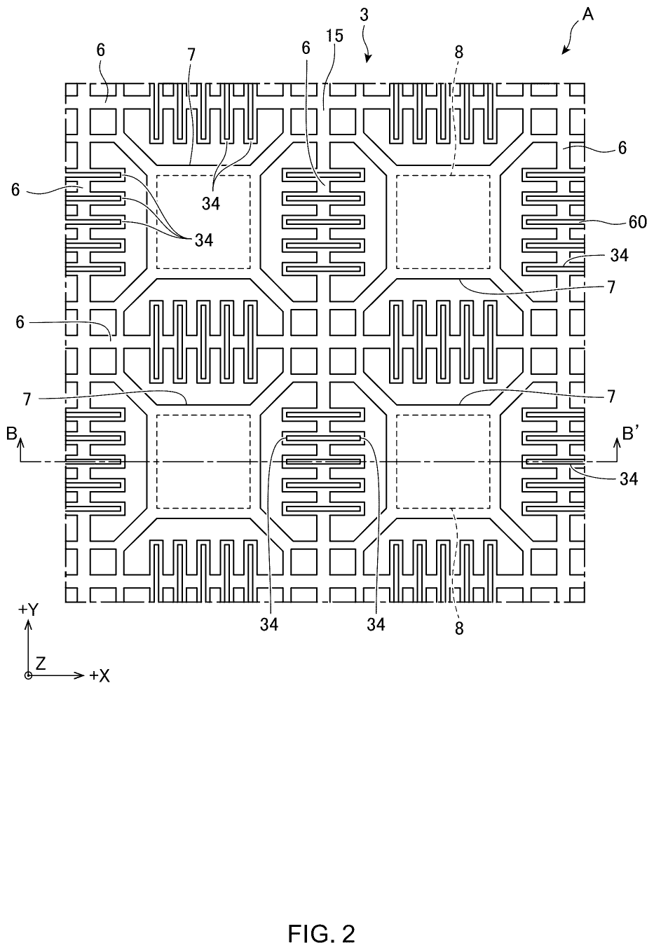

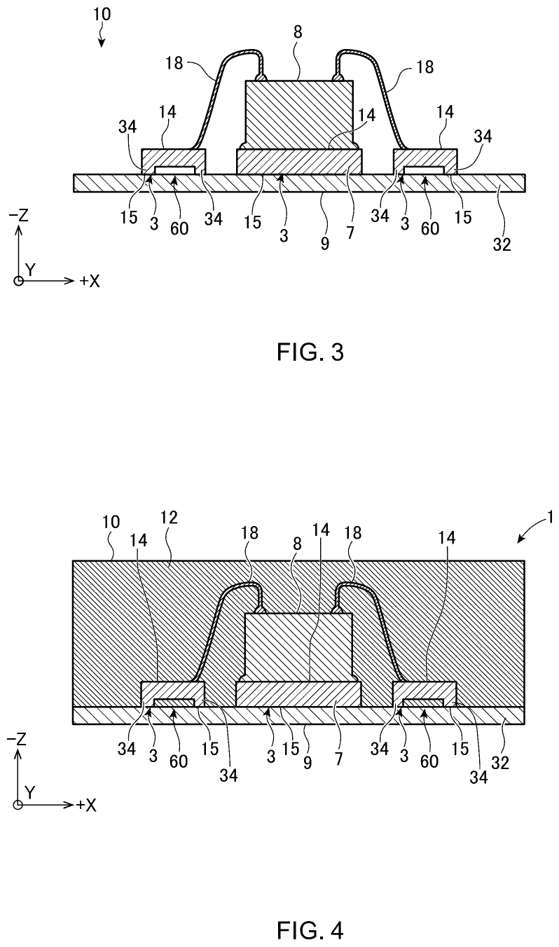

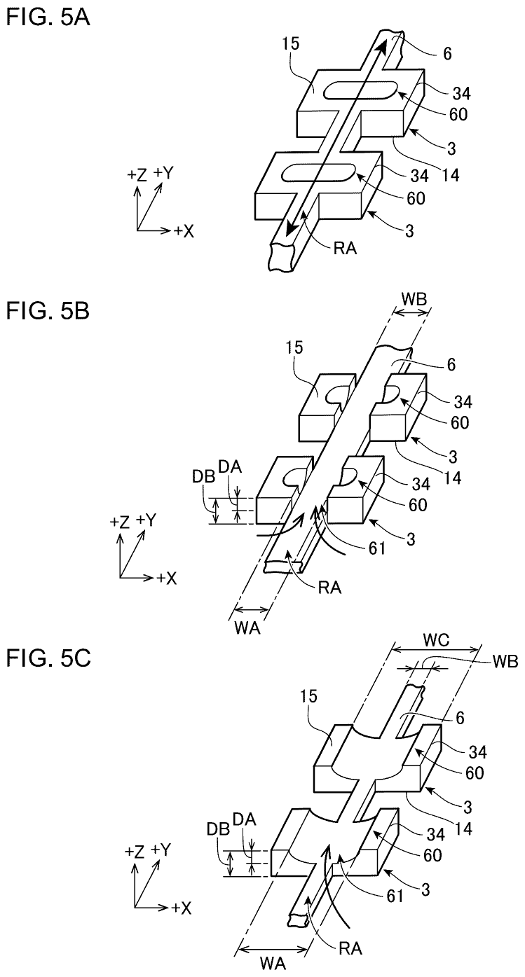

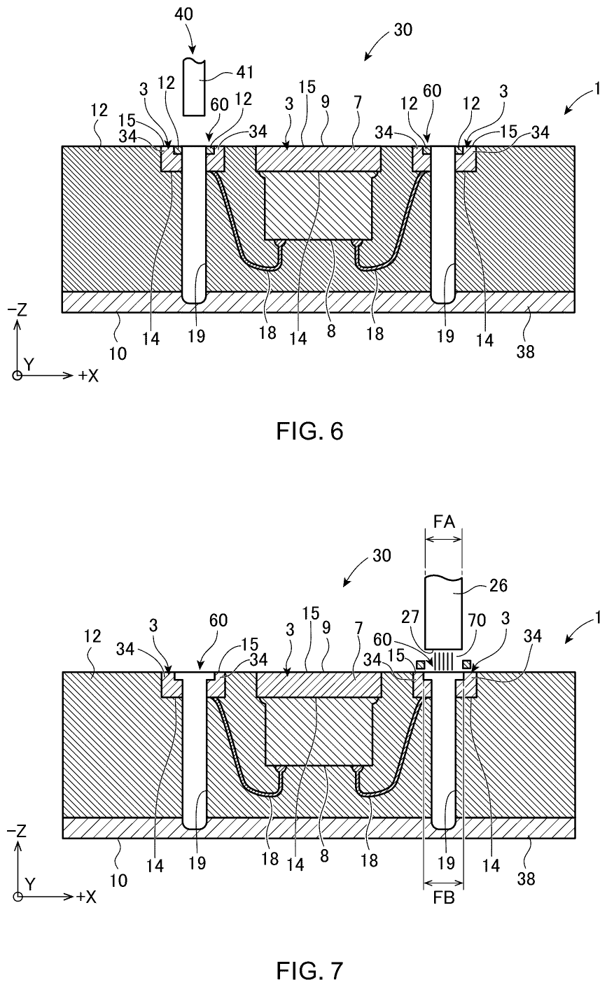

Hereinbelow, a method for manufacturing packaged device chips according to a first embodiment of the present disclosure will be described with reference to the accompanying drawings. FIG. 1 is a schematic perspective view of a package substrate for manufacturing the packaged device chips according to the first embodiment. FIGS. 2 is an enlarged view of a region A in a lead frame shown in FIG. 1. FIG. 3 is a schematic cross-sectional view to illustrate a device stacking step according to the first embodiment. FIG. 4 is a schematic view to illustrate a package substrate forming step (recess coating step) according to the first embodiment. FIG. 5A shows a comparative example of recesses formed in electrodes. FIGS. 5B and 5C show examples (present embodiment) of recesses formed in electrodes. FIG. 6 is a schematic view to illustrate a dividing step according to the first embodiment. FIG. 7 is a schematic view to illustrate a removing step according to the first embodiment.

### [Configuration of Packaged Device Chips]

The first embodiment is a method to manufacture packaged device chips 30. A package substrate 1 shown in FIG. 1 is processed through, for example, cutting and is divided into individual packaged device chips 30, as shown in FIGS. 6 and 7. According to the manufacturing method to manufacture the packaged device chips 30, device chips 8 arranged on a lead frame 3 are sealed with mold resin 12, and the package substrate 1 including the sealed device chips 8 is divided at divide-preset lines 6 into a plurality of packaged device chips 30.

The package substrate 1 is, as shown in FIG. 1, formed to have a shape of a plate, of which plane surfaces are rectangular. The package substrate 1 includes a front surface 9 to face the +Z-axis direction and a back surface 10 to face the −Z-axis direction (see FIGS. 4, 6 and 7). The package substrate 1 includes a lead frame 3 having a form of a rectangular plate. The lead frame 3 includes a first surface 14 arranged on the back surface 10 side of the package substrate 1 and a second surface 15 arranged on the front surface 9 side of the package substrate 1 (see FIG. 3). The lead frame 3 is composed of a metal including copper, in other words, a metal such as a copper alloy. The package substrate 1 may not necessarily be in the form of the rectangular plate but may be, for example, in a form of a disk-shaped wafer composed of a silicon plate or a glass plate.

On the package substrate 1, a plurality of mutually intersecting divide-preset lines 6 are set. The plurality of divide-preset lines 6 include divide-preset lines 6 that extend in parallel to a longitudinal direction (e.g., a Y-axis direction) of the lead frame 3 and divide-preset lines 6 that intersect orthogonally (e.g., X-axis direction) to the longitudinal direction of the lead frame 3 and extend in parallel (e.g., Y-axis direction) to a widthwise direction of the lead frame 3. As such, the lead frame 3 is partitioned into a plurality of supporting sections 7 by the plurality of divide-preset lines 6 that intersect with one another, and on the first surface 14 side of each supporting section 7, a device chip 8 is arranged and sealed with the mold resin 12.

The package substrate 1 includes so-called QFN (Quad Flat Non-leaded Package) package substrates, in which the device chips 8 are mounted on the metal-made lead frame 3 and sealed with the mold resin 12. Optionally, the package substrate 1 may include CSP (Chip Scale Packaging) substrates.

In the first embodiment, further, the package substrate 1 is provided with alignment marks 13 on each end of the divide-preset lines 6, indicating cutting positions for cutting along the divide-preset lines 6, on the second surface 15 (the front surface 9) of the lead frame 3. In the first embodiment, each alignment mark 13 is located at a position a widthwise center of each divide-preset line 6 along a longitudinal direction of the divide-preset line 6.

The divide-preset lines 6 are set through the thickness of the lead frame 3. Each supporting section 7 is composed of a part of the lead frame 3, and the device chip 8 is arranged on the first surface 14 side of the supporting section 7. As shown in FIGS. 1 and 2, the divide-preset lines 6 are arranged between the supporting sections 7, and on each of the divide-preset lines 6, a plurality of electrodes 34 to connect the device chips 8 to, for example, respective wiring boards, are arranged. In other words, a plurality of electrodes 34 are arranged across each of the divide-preset lines 6.

Therefore, as shown in FIGS. 1 and 2, the lead frame 3 has the supporting sections 7 to support the device chips 8 and the plurality of electrodes 34 formed on the outside of the supporting sections 7.

The package substrate 1 further includes, as shown in FIGS. 1, 4, 6, and 7, the mold resin 12 that seals (coats) the back surface 10 side of the package substrate 1. The mold resin 12 is composed of a thermoplastic resin. The mold resin 12 seals (coats) the device chips 8, the electrodes 34, and wires 18 and fills the divide-preset lines 6 on the first surface 14 side of the lead frame 3.

Each electrode 34 includes, as shown in FIGS. 1 and 2, a recess 60 (cavity). The recess 60 is formed to open toward the second surface 15 side of the lead frame 3 in a region RA (see FIGS. 5A-5C), which overlaps the divide-preset line 6. The recess 60 is formed in a shape of a slit elongated in a longitudinal direction of the electrode 34. Each electrode 34 is composed of a part of the lead frame 3 and, according to the first embodiment, is located at a widthwise center of the divide-preset line 6 and formed linearly in a direction intersecting orthogonally with the divide-preset line 6.

### [Method for Manufacturing Packaged Device Chips]

The method for manufacturing the packaged device chips 30 is performed by cutting the package substrate 1, on which device chips 8 located on the lead frame 3 are sealed with the mold resin 12, at the divide-preset lines 6 to divide into pieces. The method for manufacturing the packaged device chips 30 includes a package substrate forming step, a recess coating step, a dividing step, and a removing step. Optionally, the method for manufacturing the packaged device chips 30 may include a device stacking step to be performed before the package substrate forming step.

### [Device Stacking Step]

As shown in FIG. 3, in the device stacking step, on the back surface 10 side of a supporting board 32, the second surface 15 of the lead frame 3 is supported, the device chips 8 are stacked (arrayed) on the supporting sections 7 of the lead frame 3, and the stacked (arrayed) device chips 8 and the electrodes 34 on the lead frame 3 are connected through wires 18. As such, the device chips 8 are stacked (arrayed) on the first surface 14 side of the supporting sections 7, and the device chips 8 are connected with the electrodes 34 through the wires 18. FIG. 3 shows a part of a cross-section along a line B-B′ indicated in FIG. 2. In the device stacking step, by supporting the lead frame 3 with the supporting board 32, the mold resin 12 may seal the package substrate 1 easily. In the embodiment shown in FIG. 3, solely one of the device chips 8 is shown; however, a plurality of device chips 8 that are each in the same configuration are arrayed along the X-axis direction and the Y-axis direction.

### [Package Substrate Forming Step] (Recess Coating Step)

As shown in FIG. 4, the recess coating step in the first embodiment is performed simultaneously with the package substrate forming step. In other words, FIG. 4 is a schematic diagram illustrating the package substrate forming step and the recess coating step.

The package substrate forming step is performed after the device chips 8 are arrayed on the supporting sections 7 in the device stacking step. In the package substrate forming step, the lead frame 3, including the device chips 8 stacked (arrayed) on the supporting sections 7 and the electrodes 34, is covered with a mold (not shown), and the mold resin 12 is injected in the mold to seal the lead frame 3 on which the device chips 8 are stacked with the mold resin 12. As such, the device chips 8, the wires 18, and the electrodes 34 are sealed with the mold resin 12, the recesses 60 in the electrodes 34 are coated with the mold resin 12, and thereby the package substrate 1 is formed.

Each electrode 34 has openings 61 (sec FIGS. 5B-5C), each of which is continuous with the recess 60 and is open to any sideward surface of the electrode 34, and of which depth is small enough not to divide the electrode 34 apart, on the second surface 15 side. When the lead frame 3 is being sealed, the mold resin 12 is injected to flow into the recess 60, which is open toward the side of the second surface 15 side, through the opening 61 to coat the recess 60. The recesses 60 and the openings 61 are formed in advance through an etching process. Optionally, the recesses 60 and the openings 61 may be formed through a process other than etching.

As such, in the package substrate forming step, by injecting the mold resin 12 into the mold, the device chips 8 electrically connected with the electrodes 34 and the electrodes 34 are scaled with the mold resin 12, and each of the recesses 60 in the electrodes 34 are at least partly coated with the mold resin 12 flowing thereinto through the openings 61. As such, the recess coating step, in which the recesses 60 are each at least partly coated with a coating material, is performed. In the first embodiment, the coating material is the mold resin 12. Therefore, in the first embodiment, by performing the package substrate forming step, the recess coating step is performed, and the device chips 8, the electrodes 34, and the recesses 60 are sealed collectively with the mold resin 12. As such, the manufacturing operations may be shortened, and the working efficiency may be improved.

According to the present embodiment, the recesses 60 in the electrodes 34 are open toward the second surface 15 side of the lead frame 3. FIG. 5A is a perspective view of a comparative example of recesses without having the openings 61, FIG. 5B is a perspective view of an example of the recesses 60 with the openings 61 according to the present embodiment, and FIG. 5C is a perspective view of another example of recesses 60 with the openings 61 according to the present embodiment.

As shown in FIG. 5A, the recesses 60 formed in the electrodes 34 of the comparative example are open sorely toward the second surface 15 side, i.e., in +Z-axis direction. Therefore, the recesses 60 formed in the electrodes 34 of the comparative example are not open in the direction in which the divide-preset line 6 extends (extending direction) such as the X-axis direction or the Y-axis direction. In other words, the recesses 60 formed in the electrodes 34 of the comparative example are not open on any sideward surface of the electrodes 34 in the X-axis direction or the Y-axis direction. On the second surface 15 side, toward which the recesses 60 are open, the lead frame 3 is supported by the supporting board 32, and the recesses 60 are therefore closed. Thus, even when the mold resin 12 is injected in the mold, the mold resin 12 would not flow into the recesses 60.

In contrast to the comparative example, in the first embodiment, as shown in FIGS. 5B and 5C, the recesses 60 formed in the electrodes 34 each have the opening 61, which is open to the sideward surface of the electrode 34 where the divide-preset line 6 is formed, and which does not divide the electrode 34 apart. In the examples shown in FIGS. 5B and 5C, the opening 61 in a form of a groove having a depth DA, which does not divide the electrode 34 apart, is an example of the open groove. In other words, the depth DA of the opening 61 being a groove is formed to be smaller than a depth DB of the electrode 34. In the examples of FIGS. 5B and 5C, the openings 61 are formed on the surfaces of the electrode 34 on the side in the Y-axis direction, but the surfaces on which the openings 61 may be formed are not necessarily limited as long as the openings 61 are formed on any of the surfaces of the electrode 34 on the sides in the X-axis direction or the Y-axis direction with a depth DA which does not divide the electrode 34 apart. In the configuration shown in FIG. 5B, a width WA of the opening 61 is in a same width as a width WB of the divide-preset line 6. Accordingly, in the package substrate forming step, for filling the molds with the mold resin 12, the mold resin 12 is allowed to flow through the openings 61 to the recesses 60. As such, the recesses 60 may be filled with the mold resin 12 and coated with the mold resin 12 easily. Accordingly, through the openings 61, the mold resin 12 is allowed to flow into the recesses 60, and the device chips 8, the electrodes 34, and the recesses 60 may be sealed collectively with the mold resin 12. Therefore, the manufacturing operations may be shortened, and the working efficiency may be improved.

In the embodiment shown in FIG. 5B, in the package substrate forming step, the mold resin 12 coats each of the recesses 60 entirely, however, the mold resin 12 may coat at least a part of each of the recesses 60. In other words, within an entire range of the recess 60, at least a range in which a cutter blade 41 (see FIG. 6) of a cutting device 40 runs may be coated with the mold resin 12.

As shown in FIG. 5C, optionally, the width WA of the opening 61 in the first embodiment may be larger than the width WB of the divide-preset line 6. In FIG. 5C, the width WA of the opening 61 is equal to a width WC of the recess 60. As such, the opening 61 may be widened; therefore, when the mold resin 12 is supplied to the recesses 60 through the openings 61 in the package substrate forming step, the openings 61 may cause the mold resin 12 to flow in the recesses 60 easily. Accordingly, the mold resin 12 may fill the recesses 60, and the recesses 60 may be coated with the mold resin 12 more reliably. Moreover, the width WA of the opening 61 may be formed to be greater than the width WC of the recess 60. Thereby, the form of the groove, through which the mold resin 12 may flow into the recess 60, may be prevented from affecting an exterior appearance of the final form of the manufactured packaged device chips 30. Accordingly, aesthetics of the packaged device chips 30 may be improved.

In the embodiments as shown in FIGS. 5B and 5C, the openings 61 are in the forms of open grooves formed to have the depth DA that does not divide the electrodes 34 apart; however, the form of the opening 61 may not necessarily be limited. For example, the opening 61 may have a form of a tubular open hole (not shown). The open hole is an example of the opening 61. The opening 61 in the tubular form may be formed through a sideward surface of the electrode 34 to the recess 60, which is located inside the electrode 34. For example, the opening 61 in the tubular form may include an open hole which is open in the +Z axis direction. With the open hole, when the mold resin 12 is supplied in the package substrate forming step, the mold resin 12 may be allowed to flow into the recesses 60 through the open holes formed in the electrodes 34. As such, the mold resin 12 may fill the recesses 60, and the recesses 60 may be coated with the mold resin 12 easily.

### [Dividing Step]

As shown in FIG. 6, in the dividing step, by dividing the package substrate 1 along the divide-preset lines 6 at regions RA (in particular, regions RA in FIGS. 5B and 5C) including the recesses 60 coated with the mold resin 12, and by cutting the electrodes 34 and the mold resin 12, the individual packaged device chips 30 are produced.

After the package substrate forming step (recess coating step) is performed, in the dividing step, first, the package substrate 1 is removed from the supporting board 32, the front surface 9 and the back surface 10 of the package substrate 1 are inverted vertically, and the package substrate 1 is held by the back surface 10 side, i.e., the mold resin 12, on a first dicing tape 38. In the dividing step, optionally, the back surface 10 side, in other words, the mold resin 12, of the package substrate 1 may be suctioned and held against a holder surface of a chuck table (not shown).

The cutting device 40 includes the cutter blade 41. The cutting device 40 is an example of the processing device. The processing device may not necessarily be limited to the cutting device 40 but may include any device as long as the device may produce the packaged device chips 30. In the dividing step, the cutting device 40 captures an image of the alignment marks 13 (sec FIG. 1) on the front surface 9 of the package substrate I held by the first dicing tape 38 with an image capturing unit (not shown) and locate the divide-preset line 6 (see FIG. 1) to align with the cutter blade 41 of the cutting device 40.

In the dividing step, the cutting device 40 cuts the package substrate 1 on the side of the lead frame 3 on which the recesses 60 are formed, in other words, on the front surface 9 side, fully with the cutter blade 41 to form machine groove 19. In particular, the first dicing tape 38 and the cutter blade 41 are moved relatively along the divide-preset line 6, and, as shown in FIG. 6, an edge of the cutter blade 41 is located at a widthwise center in the recess 60, and the cutter blade 41 is operated to cut the package substrate 1 to a depth where the electrodes 34 and the mold resin 12 are cut through but the first dicing tape 38 is not cut through. As such, the process to cut the package substrate 1 fully is performed, and the machine grooves 19 are formed in the divide-preset lines 6 in the package substrate 1. A thickness of the edge of the cutter blade 41 is smaller than or equal to the width of the recesses 60.

In the dividing step, the cutting device 40 cuts the package substrate 1 along the divide-preset lines 6 on the front surface 9 side to divide the recess 60 in each electrode 34 and each electrode 34 into two parts. Accordingly, the cutting device 40 may cut the recesses 60 formed on the package substrate 1 along the divide-preset lines 6 at the respective widthwise center to divide the package substrate 1 into the individual packaged device chips 30. As such, the packaged device chips 30 are produced.

After the package substrate forming step (recess coating step), each of the recesses 60 is at least partly coated with the mold resin 12. In other words, as shown in FIG. 6, the mold resin 12 seals (coats) the device chips 8 and recesses 60 in the electrodes 34 while the lead frame 3 is exposed on the front surface 9 side. As such, the recesses 60 in the electrodes 34 are coated with the mold resin 12; therefore, when the electrodes 34 are divided at the divide-preset lines 6 in the dividing step, the mold resin 12 being the coating material may prevent formation of burrs. Accordingly, in the dividing step, by dividing the package substrate 1 along the divide-preset lines 6 at the regions RA including the recesses 60 which are coated with the mold resin 12, burrs that may otherwise be produced when the electrodes 34 are divided may be reduced while the packaged device chips 30 are produced. After the dividing step, the removing step is performed.

### [Removing Step]

As shown in FIG. 7, in the removing step, a high-pressure fluid is jetted at the mold resin 12 coating the recesses 60 to remove the mold resin 12 from the recesses 60. In FIG. 7, the mold resin 12 is an example of the coating material. When the mold resin 12 is cut and divided in the dividing step, the mold resin 12 remains in the recesses 60. For example, within the mold resin 12 coating the recesses 60, some of the mold resin 12 coating specific areas, such as central areas of the recesses 60, where the cutter blade 41 contacts the mold resin 12, may be removed easily by the cutter blade 41. In contrast, some of the mold resin 12 coating other specific areas of the recesses 60, where the cutter blade 41 does not contact the mold resin 12, such as corners of the recesses 60, may not be removed by the cutter blade 41 but may remain therein. With the mold resin 12 remaining in the recesses 60, in a later process, the remaining mold resin 12 may scatter and cause contamination. Therefore, in the removing step of the first embodiment, for removing the mold resin 12, which is the coating material, from the recesses 60, the high-pressure fluid is jetted at the remaining mold resin 12 that coats the recesses 60 using a high-pressure waterjet nozzle 26.

The high-pressure waterjet nozzle 26 may consist of, for example, a waterjet nozzle that may be used in a waterjet saw and is fixed to the cutting device 40 with a fixing device (not show). Therefore, the high-pressure waterjet nozzle 26 is movable integrally with the cutting device 40. The high-pressure waterjet nozzle 26 is an example of the fluid-jet device. The high-pressure waterjet nozzle 26 has a cylindrical shape extending in the vertical direction, and at a lower end thereof, a jet opening 27, through which high-pressure water (hereinbelow called “high-pressure water 70”) pressurized to a predetermined level of pressure may be jetted toward the package substrate 1, is formed. The high-pressure water 70 is an example of the fluid. The fluid may be, for example, a liquid other than high-pressure water such as a solution, a mixture liquid, or a cleaning liquid. Optionally, the fluid may be a gas such as air that may be jetted at a high pressure.

The jet opening 27 is continuous with a flow path (not shown) formed inside the high-pressure waterjet nozzle 26, and the flow path is connected with a high-pressure water supply source (not shown) through a tube (not shown). The high-pressure water supply source may supply the high-pressure water 70 pressurized by a compressor (not shown) to the high-pressure waterjet nozzle 26. It is preferable that the pressure of the high-pressure water 70 to be jetted from the high-pressure waterjet nozzle 26 is adjusted to an intensity that may not damage the recesses 60 in the package substrate 1.

The jet opening 27 is formed to have a width FA, which is larger than a width FB of the recesses 60, and an outer diameter thereof may be, for example, 300 μm. As the jet opening 27 is formed to have the width FA larger than the width FB of the recesses 60, without moving the first dicing tape 38 that supports the packaged device chip 30 in the horizontal direction, a single stroke of the high-pressure water 70 jetted at the entire width FB of the recess 60 may remove the mold resin 12 adhered to the packaged device chip 30. As such, the removing process to the packaged device chips 30 may be simplified, and a speed of the operation may be improved. In the embodiment described above, a single stroke of the high-pressure water 70 is jetted at the packaged device chip 30; however, optionally, two or more strokes of the high-pressure water 70 may be jetted.

In the removing step, the mold resin 12 remaining to coat the recesses 60 may be removed by the high-pressure water 70 jetted at the mold resin 12. Accordingly, the mold resin 12 may be prevented from adhering to an interior of the processing apparatus to cause contamination.

Optionally, the width FA of the jet opening 27 may be formed to be smaller than the width FB of the recesses 60. In the case where the jet opening 27 is formed to have the width FA smaller than the width FB of the recesses 60, by moving the first dicing tape 38 that supports the packaged device chip 30 in the horizontal direction, the high-pressure water 70 may be jetted at the entire width FB of each recess 60 to remove the mold resin 12 adhered to the packaged device chip 30. For example, by moving the first dicing tape 38 in the horizontal direction, the jet opening 27 may be moved leftward and rightward of the process groove 19 and jet the high-pressure water 70 in two strokes at the packaged device chip 30. In this embodiment, the high-pressure water 70 may be jetted in two strokes; however, optionally, the high-pressure water 70 may be jetted in a single stroke. In this configuration, the jet opening 27 may be downsized, and a degree of freedom to configure the processing apparatus may be increased. In the embodiment described above, the first dicing tape 38 is moved in the horizontal direction; however, optionally, the high-pressure waterjet nozzle 26 may be moved horizontally.

In the embodiment described above, the cutting device 40 is equipped with the cutter blade 41; however, optionally, the cutting device 40 may be equipped with other device that may cut and divide the recesses 60 such as a laser. As such, the present embodiment may be applied to various types of cutting devices 40, and the degree of freedom to configure the processing apparatus may be improved.

According to the first embodiment, the thickness of the edge of the cutter blade 41 is smaller than or equal to the width of the recesses 60; however, the thickness of the edge of the cutter blade 41 is not necessarily limited. For example, the thickness of the edge of the cutter blade 41 may be substantially equal to the width of the recesses 60. Thereby, when the package substrate 1 is cut with the cutter blade 41, the mold resin 12 coating the recesses 60 may be removed simultaneously. In this configuration, the removing step to jet the high-pressure fluid at the mold resin 12 to remove the coating material including the mold resin 12 may be omitted. Accordingly, the processing procedure may be simplified.

According to the first embodiment, the device chips 8 and the electrodes 34 are sealed with the mold resin 12, and the mold resin 12 flowing through the openings 61 into the recesses 60 in the electrodes 34 coats each of the recesses 60 at least partly. Accordingly, the recess coating step, in which the recesses 60 are coated with the mold resin 12 at least partly, is performed. As such, in the first embodiment, by performing the package substrate forming step, the recess coating step is performed, and the device chips 8, the electrodes 34, and the recesses 60 may be collectively sealed with the mold resin 12, and thereby the manufacturing operations may be shortened. Accordingly, the working efficiency may be improved.

Moreover, according to the first embodiment, in the package substrate forming step, the mold resin 12 may be fed through the openings 61 to the recesses 60. As such, with the mold resin 12 flowing through the openings 61 to the recesses 60, the device chips 8, the electrodes 34, and the recesses 60 may be collectively sealed, and thereby the manufacturing operations may be shortened. Accordingly, the working efficiency may be improved.

Moreover, according to the first embodiment, in the package substrate forming step (recess coating step), the mold resin 12 seals (coats) the device chips 8 and the recesses 60 in the electrodes 34. Therefore, while at least the recesses 60 in the electrodes 34 are coated with the mold resin 12, when the electrodes 34 arranged on the divide-preset lines 6 are divided in the dividing step, the mold resin 12 may prevent the electrodes 34 from forming burrs. Accordingly, in the dividing step, the packaged device chips 30 may be produced while burrs to be formed when the electrodes 34 are divided may be reduced. Moreover, in the removing step according to the first embodiment, the high-pressure water 70 is jetted at the mold resin 12 remaining to coat the recesses 60 to remove the mold resin 12 therefrom. Accordingly, the mold resin 12 may be prevented from adhering to an interior of the processing apparatus to cause contamination.

### Second Embodiment

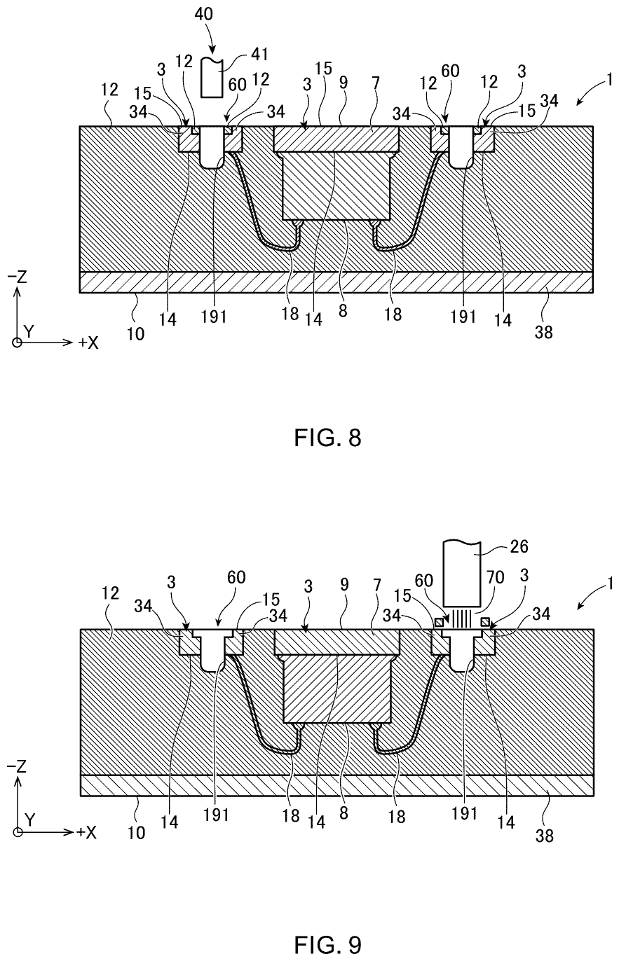

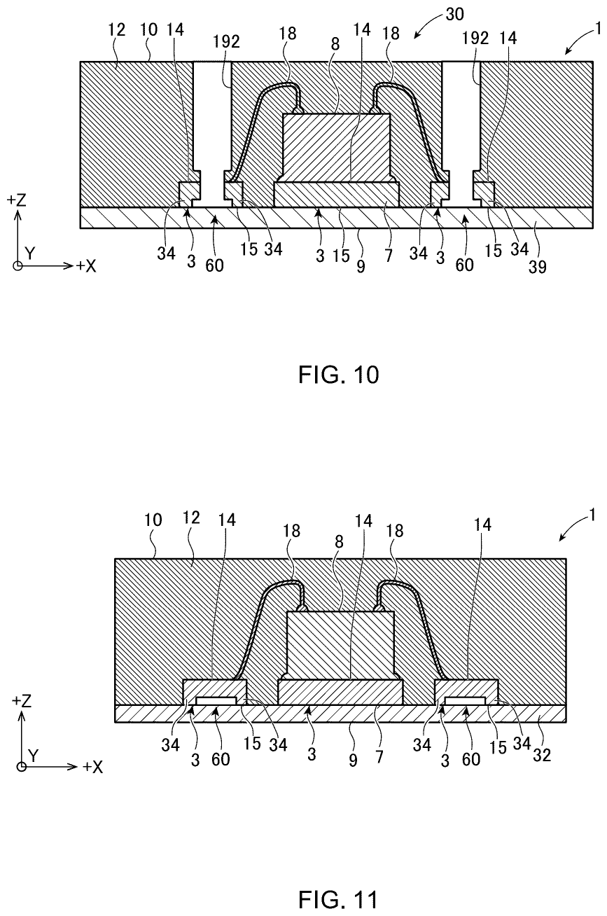

Next, with reference to the accompanying drawings, a method for manufacturing the packaged device chips according to a second embodiment will be described. In the paragraphs below, components that are common to those in the first embodiment may be referred to by the same reference signs, and description of those may be omitted. FIG. 8 is a schematic view to illustrate a first dividing step according to the second embodiment. FIG. 9 is a schematic view to illustrate a removing step according to the second embodiment. FIG. 10 is a schematic view to illustrate a second dividing step according to the second embodiment.

In the second embodiment, the package substrate 1 is divided into packaged device chips 30, of which dimensions are approximately 1 mm by 1 mm. In other words, the packaged device chips 30 are smaller in the size. When the size of the chips are smaller, if the coating material is removed from the recesses 60 with the jet of the high-pressure fluid, as it is in the removing step in the first embodiment, the packaged device chips 30 may be scattered by the pressure of the high-pressure fluid. Therefore, according to the method to manufacture the packaged device chips in the second embodiment, the device stacking step, the package substrate forming step, and the recess coating steps are performed in the same manner as those in the first embodiment. Meanwhile, the dividing step according to the second embodiment to be performed thereafter includes a first dividing step (a first processing step), in which first process grooves 191 having a depth not dividing the package substrate 1 apart are formed from the second surface 15 side of the lead frame 3, and a second dividing step (a second processing step), in which second process grooves 192 that are continuous with the first process grooves 191 are formed to divide the package substrate 1 apart. The removing step in the second embodiment is performed between the first dividing step and the second dividing step. The first dividing step and the second dividing step are an example of the dividing step.

### [First Dividing Step]

As shown in FIG. 8, in the first dividing step, the first process grooves 191 having the depth that does not divide the package substrate 1 apart are formed on the second surface 15 side of the lead frame 3. The depth from the front surface 9 side that does not divide the package substrate 1 apart may mean a depth that does not penetrate the thickness of the package substrate 1, in other words, a depth that penetrates the electrode 34 but does not penetrate the mold resin 12.

First, the front surface 9 and the back surface 10 of the package substrate 1 are inverted vertically, and the package substrate 1 is held by the back surface 10 side, i.e., the mold resin 12, on the first dicing tape 38. In the first dividing step, optionally, the back surface 10 side, in other words, the mold resin 12, of the package substrate 1 may be suctioned and held against a holder surface of a chuck table (not shown).

In the first dividing step according to the second embodiment, the cutting device 40 cuts the package substrate 1 on the second surface 15 of the lead frame 3 on which the recesses 60 are formed, in other words, on the front surface 9 side of the package substrate 1, halfway with the cutter blade 41 to form the first process grooves 191. In the first dividing step, the cutting device 40 cuts the recesses 60 in the electrodes 34 along the divide-preset lines 6 from the second surface 15 side with the cutter blade 41, thereby cutting the electrodes 34 along the divide-preset lines 6 to divide each of the electrodes 34 and each of the recesses 60 into two parts.

In the first dividing step, the cutting device 40 operates to move the first dicing tape 38 and the cutter blade 41 relatively along the divide-preset line 6, and, as shown in FIG. 8, the cutter blade 41 is operated to cut the package substrate 1 with the edge at the widthwise center in the recesses 60 halfway to the depth where the electrodes 34 are cut through but the mold resin 12 is not cut through, so as to form the first process grooves 191 on the divide-preset lines 6 on the package substrate 1. In other words, in the first dividing step, by cutting the package substrate 1 halfway, the first process grooves 191, of which depth penetrates the electrodes 34 but does not penetrate the mold resin 12, are formed. Therefore, after performing the first dividing step, parts of each electrode 34 and parts of each recess 60 that are divided in half are maintained connected via the mold resin 12 on the back surface 10 side (lower surface side). After the first dividing step, the removing step is performed.

### [Removing Step]

As shown in FIG. 9, in the removing step, the high-pressure water 70 is jetted at the mold resin 12 coating the recesses 60 to remove the mold resin 12 therefrom. In FIG. 9, the mold resin 12 is an example of the coating material. The high-pressure water 70 is an example of the high-pressure fluid. In the removing step according to the second embodiment, for removing the mold resin 12, which is the coating material, from the recesses 60, the high-pressure fluid is jetted at the remaining mold resin 12 that coats the recesses 60 using the high-pressure waterjet nozzle 26.

The first process grooves 191 formed in the first dividing step are in halfway having the depth that penetrates the electrodes 34 but does not penetrate the mold resin 12, and the mold resin 12 is continuous on the back surface 10 side (lower surface side). Therefore, when the high-pressure water 70 is jetted at the mold resin 12 coating the recesses 60 in the removing step, the electrodes 34 divided in halves and the device chips 8 are connected through the mold resin 12 on the back surface 10 side (lower surface side). Therefore, in the case where the high-pressure water 70 is jetted from the high-pressure waterjet nozzle 26 to remove the mold resin 12 from the recesses 60, the packaged device chips 30 or the electrodes 34 and the device chips 8 that compose the packaged device chips 30 may be prevented from being scattered by the pressure of the high-pressure water 70. After the removing step, the second dividing step is performed.

### [Second Dividing Step]

As shown in FIG. 10, in the second dividing step, second process grooves 192 to be connected with the first process grooves 191 to divide the package substrate 1 are formed.

First, the front surface 9 and the back surface 10 of the package substrate 1 are inverted vertically, and the package substrate 1 is held by the front surface 9 side, i.e., the lead frame 3 including the electrodes 34 and the supporting section 7, on a second dicing tape 39. In the second dividing step, optionally, the front surface 9 side, in other words, the lead frame 3 including the electrodes 34 and the supporting sections 7, of the package substrate I may be suctioned and held against the holder surface of the chuck table (not shown).

In the second dividing step, the cutting device 40 forms second process grooves 192 with the cutter blade 41 on the side of the mold resin 12 on which the recesses 60 are not formed, in other words, on the back surface 10 side, to cut the package substrate 1 fully. In particular, the second dicing tape 39 and the cutter blade 41 are moved relatively along the first process groove 191, and the edge of the cutter blade 41 (not shown in FIG. 10) is located at the widthwise center of the recesses 60, and the cutter blade 41 is operated to cut the package substrate 1 to a depth where the edge of the cutter blade 41 cuts the mold resin 12 through but does not reach the electrode 34. As such, as shown in FIG. 10, the package substrate 1 is cut fully, and the second process grooves 192 are formed on the divide-preset lines 6 in the package substrate 1. A such, the mold resin 12 is cut along the divide-preset lines 6, and the parts of the halved electrodes 34 and the recesses 60 are separated from the mold resin 12.

For the packaged device chips 30 in the second embodiment, a wettable flank may be employed. The second process grooves 192 formed in the second dividing step each have a width greater than the width of the first process grooves 191 formed in the first dividing step and are cut to the depth not reaching the electrodes 34. As such, by increasing the width of the second process grooves 192 compared to the first process grooves 191, a worker may easily observe whether or not the electrodes 34 are soldered correctly, and the packaged device chips 30 may be prevent formation of burrs, which may otherwise be formed by cutting the electrodes 34 twice.

In the second dividing step, first, the front surface 9 and the back surface 10 of the package substrate 1 are inverted vertically to be held on the second dicing tape 39; however, the back surface 10 and the front surface 9 of the package substrate I may not necessarily inverted vertically. Without inverting, the manufacturing operation may be shortened. Accordingly, the working efficiency may be improved.

### Third Embodiment

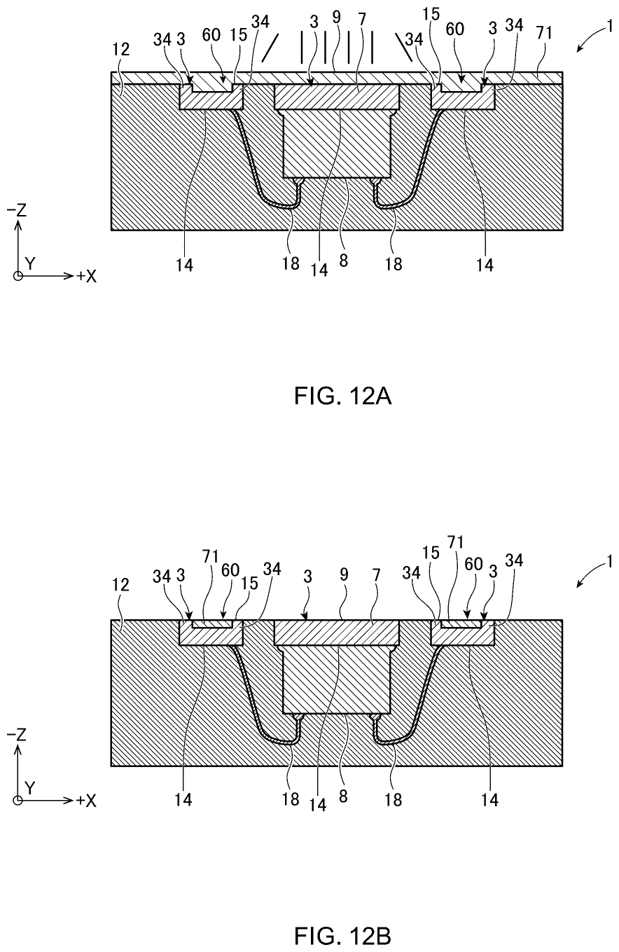

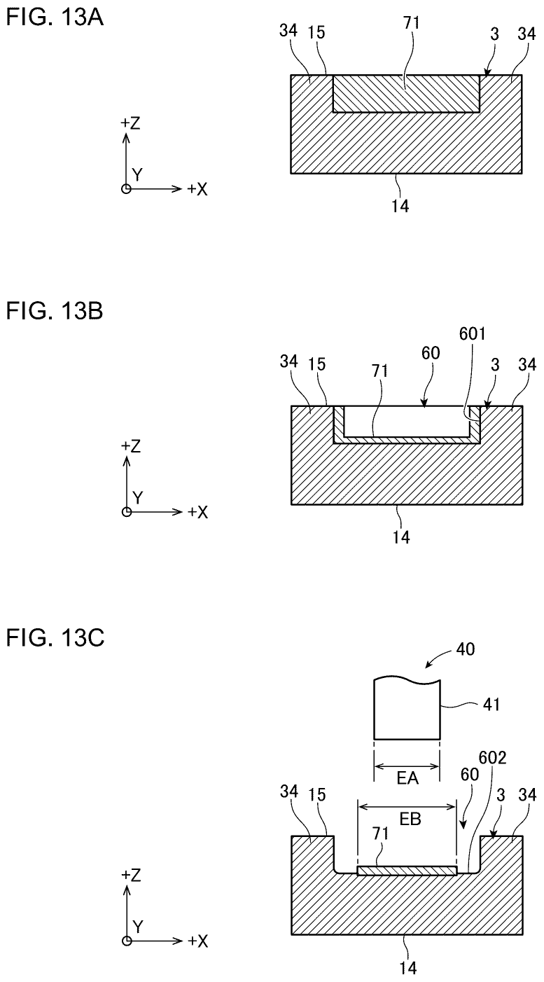

Next, with reference to the accompanying drawings, a method for manufacturing the packaged device chips according to a third embodiment will be described. In the paragraphs below, components that are common to those in the first embodiment may be referred to by the same reference signs, and description of those may be omitted. FIG. 11 is a schematic view to illustrate a package substrate forming step according to the third embodiment. FIGS. 12A and 12B are schematic views to illustrate a recess coating step according to the third embodiment. FIGS. 13A-13C are schematic views to illustrate varied examples of the recess coating step according to the third embodiment.

In the first embodiment, the mold resin 12 is used as the coating material, but a coating material 71 other than the mold resin 12 is used to coat the recesses at least partly in the third embodiment.

### [Package Substrate Forming Step]

As shown in FIGS. 11 and 12A-12B, the recess coating step according to the third embodiment is performed after the package substrate forming step, separately from the package substrate forming step.

The package substrate forming step is performed after the device chips 8 are arrayed on the supporting sections 7 in the device stacking step. In the package substrate forming step, the lead frame 3, including the device chips 8 stacked (arrayed) on the supporting sections 7 and the electrodes 34, is covered with a mold (not shown), and the mold resin 12 is injected in the mold to seal the lead frame 3 on which the device chips 8 are stacked with the mold resin 12. As such, the device chips 8, the wires 18, and the electrodes 34 are sealed with the mold resin 12, and thereby the package substrate 1 is formed. According to the third embodiment, the recesses 60 in the electrodes 34 are not coated with the mold resin 12.

As such, in the package substrate forming step, by injecting the mold resin 12 into the mold, the device chips 8 electrically connected with the electrodes 34 and the electrodes 34 are sealed with the mold resin 12, and the package substrate is formed. After the package substrate forming step, the recess coating step is performed.

### [Recess Coating Step]

As shown in FIG. 12A, in the recess coating step, the surface 9 of the package substrate 1 including each of the recesses 60 is at least partly coated with a coating material 71 other than the mold resin 12. The method to coat the package substrate 1 with the coating material 71 may be any of, for example, a spray-coating method, a transferring method in a reduced-pressure room, or a vacuum defoaming method. For the coating material 71, a resin material in any of liquid, powder, or atomized form.

The spray coating method is, as shown in FIG. 12A, a method to spray the coating material 71 in a form of liquid resin at the recesses 60. By the spray-coating method, at least a part of the recesses 60 may be coated evenly and speedily with the coating material 71. A known spray gun or an air brush may be used in the spray coating method for coating the at least a part of the recesses 60 with the coating material 71. Once the front surface 9 side of the package substrate 1 is entirely coated with the coating material 71 in the form of liquid resin in the spray-coating method, the front surface 9 of the package substrate 1 may be entirely ground so that solely the recesses 60 may stay coated with the coating material 71.

According to the transferring method in a reduced-pressure room, as shown in FIG. 12A, the package substrate 1 is located in a reduced-pressure room in which the pressure is lowered. The coating material 71 is injected in a mold (not shown) prepared in advance, and thereafter, is transferred from the mold to the recesses 60. While the coating material 71 is transferred, the coating material 71 is pressed into the recesses 60 under the reduced pressure, which may minimize air bubbles from being created, and the recesses 60 may be coated smoothly and evenly with the coating material 71. Once the front surface 9 side of the package substrate 1 is entirely coated with the coating material 71 in the form of liquid resin in the transferring method in the reduced-pressure room, as shown in FIG. 12B, the front surface 9 of the package substrate I may be entirely ground so that solely the recesses 60 may stay coated with the coating material 71.

According to the vacuum defoaming method, as shown in FIG. 12A, the coating material 71 is applied to the recesses 60. The coating material 71 shortly after the application of the coating material 71 is not cured. Next, the package substrate 1 including the recesses 60 to which the coating material 71 is applied is placed in a vacuum chamber (not shown). The air pressure in the chamber is reduced, and thereby the chamber is vacuumized. While the chamber is being vacuumized, the air bubbles in the coating material 71 may be released in the chamber. As such, the coating material 71 is degassed, and the recesses 60 may be coated evenly with the coating layer, which is dense, uniform, and not containing air bubbles. Once the front surface 9 side of the package substrate 1 is entirely coated with the coating material 71 in the form of liquid resin in the vacuum defoaming method, as shown in FIG. 12B, the front surface 9 of the package substrate 1 may be entirely ground so that solely the recesses 60 may stay coated with the coating material 71.

Optionally, as shown in FIGS. 13A, 13B, and 13C, in the recess coating step according to the third embodiment, the at least a part of the recesses 60 may be coated with a coating material 71 other than the mold resin 12.

For example, as shown in FIG. 13A, each of the recesses 60 may be entirely filled with the coating material 71. By filling the recesses 60 entirely with the coating material 71, the package substrate 1 having the recesses 60 may prevent burrs from being formed therein reliably.

For another example, as shown in FIG. 13B, merely a surface 601 of each recess 60 may be coated with the coating material 71. By coating the surfaces 601 of the recesses 60, the package substrate 1 having the recesses 60 may prevent burrs from being formed therein, and an amount of the coating material 71 to be used may be reduced so that the processing cost may be reduced.

For another example, as shown in FIG. 13C, the coating material 71 may coat a width EB on a bottom surface 602 of each recess 60, which is greater than or equal to a width EA to be cut by the cutter blade 41 of the cutting device 40. By coating the width EB, the package substrate 1 having the recesses 60 may prevent burrs from being formed therein, and an amount of the coating material 71 to be used may be minimized so that the processing cost may be reduced.

Embodiment of the present disclosure may not necessarily be limited to the configurations described above or in the modified example but may be modified, substituted, or altered in various ways without departing from the spirit of the technical idea of the present disclosure. Furthermore, if the technical idea of the present disclosure may be realized in a different way due to technological progress or other derived technology, it may be implemented with use of the method. Therefore, the claims cover all embodiments that may be included within the scope of the technical idea of the present disclosure.

As described above, the method to manufacture the packaged device chips may reduce burrs in the package substrate having recesses. Therefore, the method is advantageous in a package substrate having recesses and in any processing apparatus that may produce packaged device chips.

1. A method for manufacturing packaged device chips by dividing a package substrate, on which device chips arrayed on a lead frame are sealed with a mold resin, along divide-preset lines, the lead frame including a plurality of supporting sections to support the device chips on a first surface side thereof and a plurality of electrodes formed on outsides of the supporting sections, the plurality of electrodes each including a recess which is open on a second surface side of the lead frame opposite to the first surface side, the recess being formed in a region to overlap any of the divide-preset lines, the method comprising:
forming the package substrate by sealing the device chips arrayed on the supporting sections and the plurality of electrodes with the mold resin,
coating each of the recesses at least partly with a coating material;
dividing regions including the recesses coated with the coating material along the divide-preset lines to produce the packaged device chips; and
jetting a high-pressure fluid at the coating material coating the recesses to remove the coating material from the recesses.

2. The method according to claim 1,
wherein each of the plurality of electrodes has an opening continuous with the recess therein on the second surface side, the opening being open on any sideward surface of the electrode without dividing the electrode apart, and
wherein the recess coating includes causing the mold resin to flow into the recesses through the openings during the package substrate forming.

3. The method according to claim 1,
wherein the dividing further includes:
a first dividing, including forming first process grooves having a depth from the second surface side that does not divide the package substrate apart; and
a second dividing, including forming second process grooves, the second process grooves being continuous respectively with the first process grooves and dividing the package substrate apart, and
wherein the removing of the coating material from the recesses is performed between the first dividing and the second dividing.
